(19) United States
(12) Patent Application Publication
(10) Pub. No.: US 2020/0285418 A1
(43) Pub. Date: Sep. 10, 2020

(54) MEMORY SYSTEM

(71) Applicant: TOSHIBA MEMORY CORPORATION, Minato-ku (JP)

(72) Inventor: Tokumasa HARA, Kawasaki (JP)

(73) Assignee: TOSHIBA MEMORY CORPORATION, Minato-ku (JP)

(21) Appl. No.: 16/554,039

(22) Filed: Aug. 28, 2019

(30) Foreign Application Priority Data
Mar. 7, 2019 (JP) 2019-041589

(51) Int. Cl. G06F 3/06; G11C 16/04; G11C 16/30; G11C 16/08; G11C 16/26

(52) U.S. Cl. CPC G06F 3/0659; G06F 3/0679; G06F 3/0619; G11C 16/26; G11C 16/30; G11C 16/08; G11C 16/0483

(57) ABSTRACT

According to an embodiment, a memory system is connectable to a host. The memory system includes a memory controller and a memory chip. The memory chip includes a processing circuit and a first storage area including a plurality of word lines. The memory controller is configured to cause the processing circuit to execute a first access to the first storage area. The memory controller is configured to transmit a first command to the memory chip after completion of the first access. The memory controller is configured to transmit a second command to the memory chip before causing the processing circuit to execute a second access subsequent to the first access. The processing circuit is configured to start applying a first voltage to the word lines in response to the first command, and end applying the first voltage to the word lines in response to the second command.

### CROSS-REFERENCE TO RELATED APPLICATIONS

This application is based upon and claims the benefit of priority from Japanese Patent Application No. 2019-041589, filed on Mar. 7, 2019; the entire contents of which are incorporated herein by reference.

### FIELD

Embodiments described herein relate generally to a memory system.

### BACKGROUND

A memory system including a memory cell transistor has been known. A threshold voltage of the memory cell transistor is set to a state corresponding to data, whereby the memory cell transistor can hold data in a non-volatile manner.

However, the threshold voltage decreases over time in reality. Thus, without any countermeasure, the data varies due to the decrease of the threshold voltage. A period from when data is stored in the memory cell transistor to when the data is varied is referred to as data retention. It is preferable to elongate the data retention.

### BRIEF DESCRIPTION OF THE DRAWINGS

FIG. 1 is a diagram illustrating an example of a configuration of a memory system 1 of a first embodiment;

FIG. 2 is a diagram illustrating an example of a configuration of a memory chip 100 of the first embodiment;

FIG. 3 is a schematic diagram illustrating a configuration of a memory cell array 121 of the first embodiment;

FIG. 4 is a diagram illustrating a circuit configuration of a block BLK of the first embodiment;

FIG. 5 is a cross-sectional view of a partial region of the block BLK according to the first embodiment;

FIG. 6 is a graph illustrating an example of a possible threshold voltage of the memory cell of the first embodiment;

FIG. 7 is a schematic diagram illustrating an example of a configuration of a voltage generation circuit 116 of the first embodiment;

FIG. 8 is a flowchart illustrating an operation of setting a voltage Vrs by a memory controller 200 of the first embodiment;

FIG. 9 is a graph illustrating an example of a relationship between a detected value of a temperature sensor and a set value of the voltage Vrs in the first embodiment;

FIG. 10 is a graph illustrating an example of a relationship between the number of P/E cycles and the set value of the voltage Vrs in the first embodiment;

FIG. 11 is a flowchart illustrating an example of a method of controlling the memory chip 100 by the memory controller 200 of the first embodiment;

FIG. 12 is a flowchart illustrating an example of an operation of determining whether a transition condition is satisfied by the memory controller 200 of the first embodiment;

FIG. 13 illustrates an example of a waveform of a voltage to be applied to each part in an RS state in the first embodiment;

FIG. 14 illustrates an example of timing at which the memory controller 200 of the first embodiment transmits and receives information to and from each of the memory chips 100 and state transition timing of the memory cell array 121;

FIG. 15 illustrates an example of state transition of various signal lines when an RS entry command and an RS exit command are transmitted according to the first embodiment;

FIG. 16 illustrates an example of state transition of various signal lines when a set feature command for setting the voltage Vrs is transmitted in the first embodiment;

FIG. 17 illustrates an example of timing at which the memory controller 200 transmits and receives information to and from each of the memory chips 100 and state transition timing of the memory cell array 121 in the second embodiment; and

FIG. 18 illustrates an example of state transition of various signal lines when an RS entry command and an RS exit command are transmitted in the second embodiment.

### DETAILED DESCRIPTION

According to an embodiment, in general, a memory system is connectable to a host. The memory system includes a memory controller and a memory chip. The memory chip includes a processing circuit and a first storage area including a plurality of word lines. The memory controller is configured to cause the processing circuit to execute a first access to the first storage area. The memory controller is configured to transmit a first command to the memory chip after completion of the first access. The memory controller is configured to transmit a second command to the memory chip before causing the processing circuit to execute a second access subsequent to the first access. The processing circuit is configured to start applying a first voltage to the word lines in response to the first command, and end applying the first voltage to the word lines in response to the second command.

Hereinafter, exemplary embodiments of a memory system will be described in detail with reference to the attached drawings. The following embodiments are merely illustrative and not intended to limit the scope of the present invention.

### First Embodiment

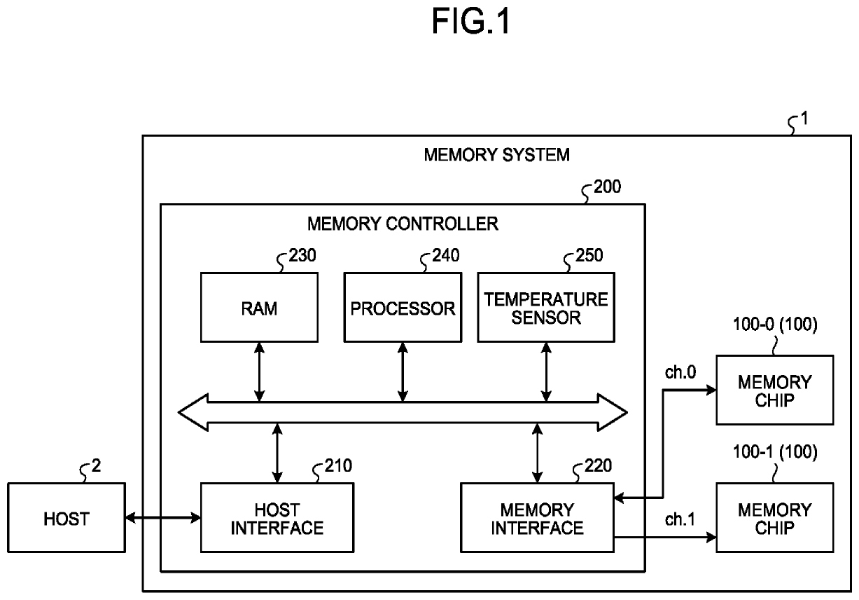

FIG. 1 is a diagram illustrating an example of a configuration of a memory system of a first embodiment. As illustrated in FIG. 1, a memory system 1 is connectable to a host 2. The host 2 represents, for example, a server, a personal computer, or a mobile information processing device. The memory system 1 functions as an external storage device of the host 2. The host 2 can issue a request to the memory system 1. The request includes a read request and a write request.

The memory system 1 includes one or more memory chips 100 and a memory controller 200. Herein, the memory system 1 includes memory chips 100-0 and 100-1 as the one or more memory chips 100.

Each of the memory chips 100 is, for example, a NAND flash memory. Each of the memory chips 100 may be a NOR flash memory.

The two memory chips 100 are connected to the memory controller 200 via different channels. In the example of FIG. 1, the memory chip 100-0 is connected to the memory controller 200 via the channel 0 (ch.0), and the memory chip 100-1 is connected to the memory controller 200 via the channel 1 (ch.1).

Each channel is a wiring group including an IO signal line and a control signal line. The IO signal line is, for example, a signal line for transmitting and receiving data, an address, and a command. The control signal line is, for example, a signal line for transmitting and receiving a write enable (WE) signal, a read enable (RE) signal, a command latch enable (CLE) signal, an address latch enable (ALE) signal, a ready/busy (Ry/By) signal, and the like.

The memory controller 200 can control the respective channels individually. The memory controller 200 can operate the two memory chips 100 asynchronously by individually controlling the two channels.

The number of the memory chips 100 in the memory system 1 is not limited to two. The number of the channels in the memory system 1 is not limited to two. The number of the memory chips 100 connected to each channel may be two or more.

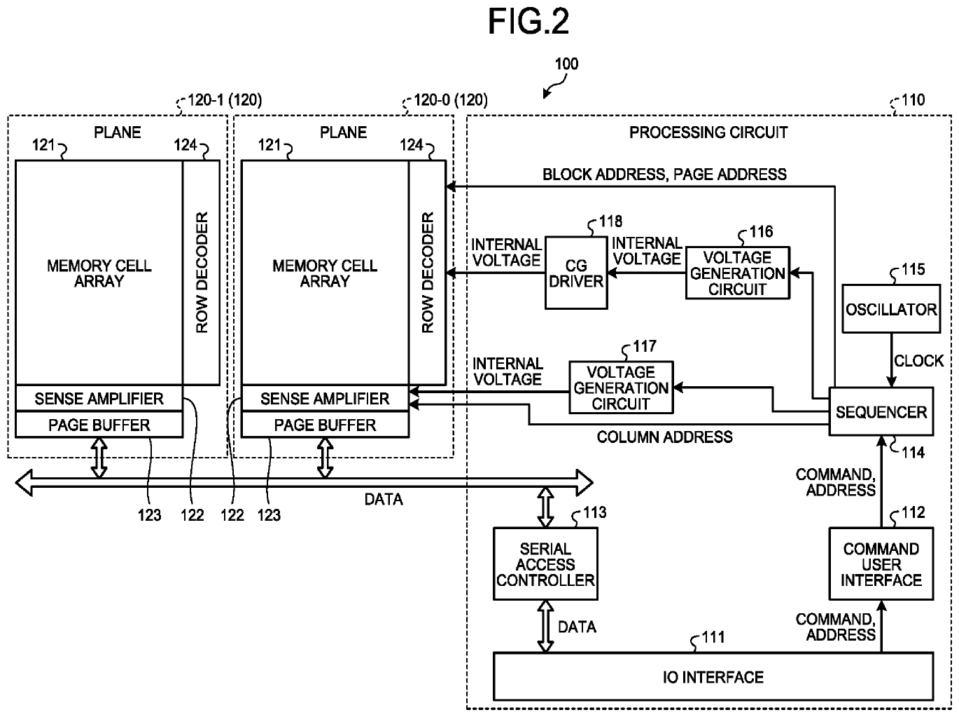

FIG. 2 is a diagram illustrating an example of a configuration of the memory chip 100 of the first embodiment.

The memory chip 100 includes a processing circuit 110 and a plurality of planes 120. Herein, the memory chip 100 includes a plane 120-0 and a plane 120-1 as an example.

Each of the planes 120 includes a memory cell array 121, a sense amplifier 122, a page buffer 123, and a row decoder 124. The sense amplifier 122, the page buffer 123, and the row decoder 124 constitute a peripheral circuit to access the memory cell array 121. Thus, the memory cell array 121 can be accessed in units of the planes 120.

The access to the memory cell array 121 includes a program operation for writing data to the memory cell array 121, a read operation of data from the memory cell array 121, and an erase operation to data stored in the memory cell array 121. The processing circuit 110 executes various types of processing including the program operation, the read operation, and the erase operation in response to a command from the memory controller 200. In this disclosure, a command that causes the memory chip 100 to execute the program operation will be referred to as a program command. A command that causes the memory chip 100 to execute the read operation will be referred to as a read command. A command that causes the memory chip 100 to execute the erase operation will be referred to as an erase command.

The transmission of the program command, the read command, or the erase command to the memory chip 100 to execute write, read, or erase of data by the memory controller 200 may be referred to as the access to the memory chip 100.

In addition, the execution of the program operation, the read operation, or the erase operation by the processing circuit 110 may be referred to as the access to the memory cell array 121.

The processing circuit 110 includes an IO interface 111, a command user interface 112, a serial access controller 113, a sequencer 114, an oscillator 115, a voltage generation circuit 116, a voltage generation circuit 117, and a control gate (CG) driver 118.

The IO interface 111 is a circuit to transmit and receive an IO signal and a control signal to and from the memory controller 200.

The command user interface 112 acquires, from the control signal, a command and an address out of the command, the address, and data received from the memory controller 200 via the IO signal line. The command user interface 112 sends the acquired command and address to the sequencer 114.

The oscillator 115 is a circuit that generates a clock. The clock generated by the oscillator 115 is supplied to the respective elements including the sequencer 114.

The sequencer 114 is a state machine that is driven by the clock supplied from the oscillator 115. The sequencer 114 executes control such as the access to the memory cell array 121.

For example, the sequencer 114 issues an instruction to control various internal voltages and operation timing in response to receipt of the command from the command user interface 112. The sequencer 114 supplies a block address and a page address included in the address received from the command user interface 112 to the row decoder 124 of the corresponding plane 120. In addition, the sequencer 114 supplies a column address included in the address received from the command user interface 112 to the sense amplifier 122 of the corresponding plane 120.

The voltage generation circuit 116 generates various internal voltages to be supplied to a word line. The voltage generation circuit 117 generates various internal voltages supplied to a bit line.

The CG driver 118 supplies the various internal voltages generated by the voltage generation circuit 116 to one of the two row decoders 124 in the plane 120 serving as an access destination.

In the program operation, the serial access controller 113 stores data, received serially for each bit width of the IO signal line, in one of the two page buffers 123 corresponding to the memory cell array 121 serving as a write destination. In the read operation, the serial access controller 113 divides data, stored in one of the two page buffers 123 corresponding to the memory cell array 121 serving as a read destination, for each bit width of the IO signal line and sequentially sends the divided data to the IO interface 111.

Each of the row decoders 124 decodes the block address and the page address in the program operation and the read operation, and selects a word line corresponding to a target page of the block BLK serving as an access destination. Then, each of the row decoders 124 applies appropriate voltages to the selected word line and an unselected word line.

Each of the sense amplifiers 122 transfers corresponding data from the page buffer 123 to the memory cell transistor in the program operation.

In addition, each of the sense amplifiers 122 senses data, read from the selected word line to the bit line, and stores the obtained data in the corresponding page buffer 123 in the read operation. The data is sent from the page buffer 123 to the memory controller 200 via the serial access controller 113 and the IO interface 111.

Next, a configuration of the memory cell array 121 of the first embodiment will be described.

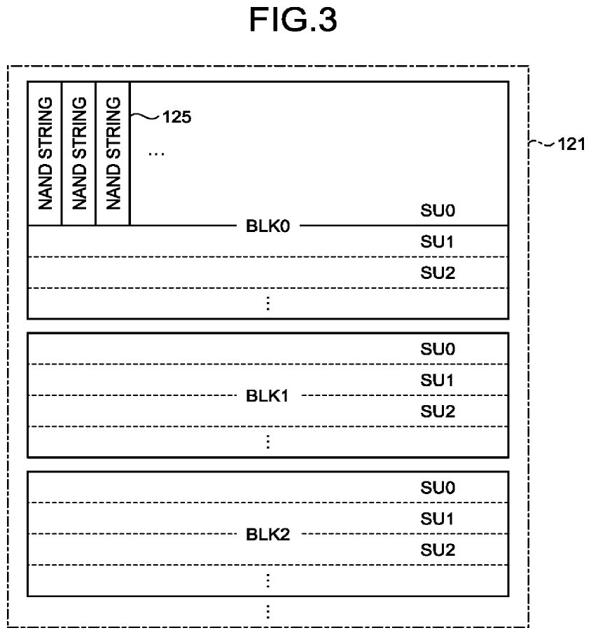

FIG. 3 is a schematic diagram illustrating the configuration of the memory cell array 121 of the first embodiment. Each of the memory cell arrays 121 includes a plurality of blocks BLK (BLK0, BLK1, and so on) each of which is a set of a plurality of non-volatile memory cell transistors. Each of the blocks BLK includes a plurality of string units SU (SU0, SU1, and so on) each of which is a set of memory cell transistors associated with word lines and bit lines. Each of the string units SU includes a plurality of NAND strings 125 in which the memory cell transistors are connected in series. The number of the NAND strings 125 in the string unit SU is optional.

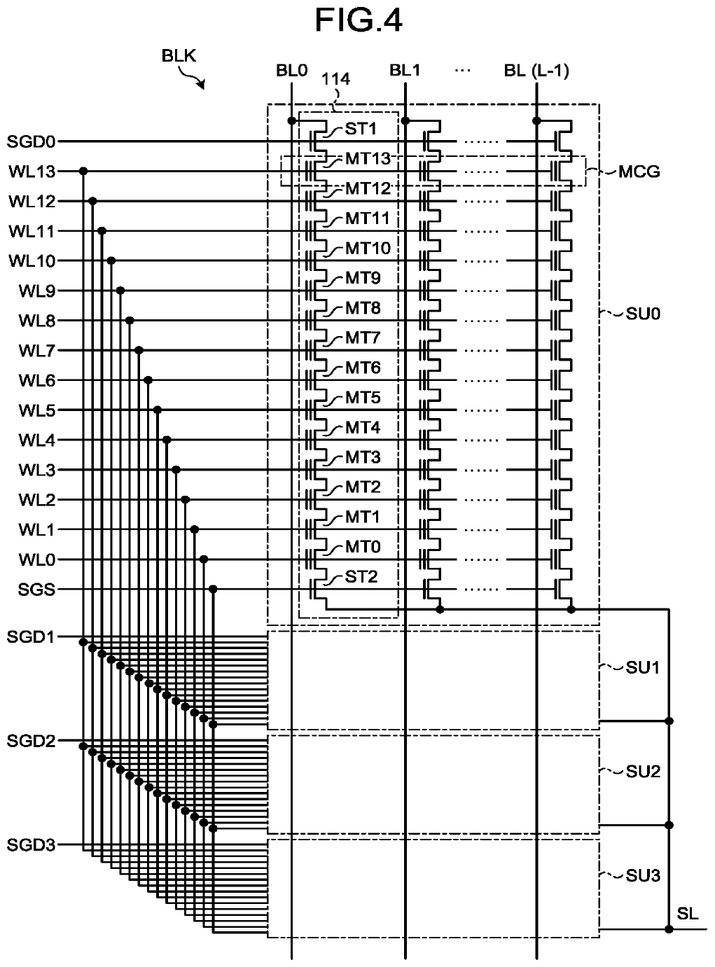

FIG. 4 illustrates a circuit configuration of the block BLK of the first embodiment. The respective blocks BLK have the same configuration. The block BLK includes, for example, four string units SU0 to SU3. Each of the string units SU includes the NAND strings 125.

Each of the NAND strings 125 includes, for example, fourteen memory cell transistors MT (MT0 to MT13) and select transistors ST1 and ST2. The memory cell transistor MT includes a control gate and a charge storage layer, and holds data in a non-volatile manner. Then, the fourteen memory cell transistors MT (MT0 to MT13) are connected in series between a source of the select transistor ST1 and a drain of the select transistor ST2. The memory cell transistor MT may be a MONOS transistor including an insulating film as the charge storage layer, or may be an FG transistor including a conductive film as the charge storage layer. The number of the memory cell transistors MT in the NAND string 125 is not limited to fourteen.

Gates of the select transistors ST1 in the respective string units SU0 to SU3 are connected to select gate lines SGD0 to SGD3, respectively. Meanwhile, gates of the select transistors ST2 in the respective string units SU0 to SU3 are commonly connected to, for example, a select gate line SGS. The gates of the select transistors ST2 in the respective string units SU0 to SU3 may be connected to different select gate lines SGS0 to SGS3 for each of the string units SU. Control gates of the memory cell transistors MT0 to MT13 in the same block BLK are commonly connected to word lines WL0 to WL13, respectively.

Drains of the select transistors ST1 of the NAND strings 125 in the string unit SU are connected to different bit lines BL, i.e., BL0 to BL (L−1), respectively, where L is a natural number of two or more. In addition, the bit line BL commonly connects one NAND string 125 of each of the string units SU among the blocks BLK. Sources of the select transistors ST2 are commonly connected to a source line SL.

That is, the string unit SU is a set of the NAND strings 125 connected to different bit lines BL and connected to the same select gate line SGD. The block BLK is a set of the string units SU sharing the word line WL. Each of the memory cell arrays 121 is a set of the blocks BLK sharing the bit line BL.

The data program and read operations are collectively performed on the memory cell transistors MT connected to one word line WL in one string unit SU. Hereinafter, a group of the memory cell transistors MT to be selected collectively in the data program and read operations will be referred to as a “memory cell group MCG”. An aggregate of one-bit data to program or read to or from one memory cell group MCG will be referred to as a “page”. Data can be erased in units of the blocks BLK.

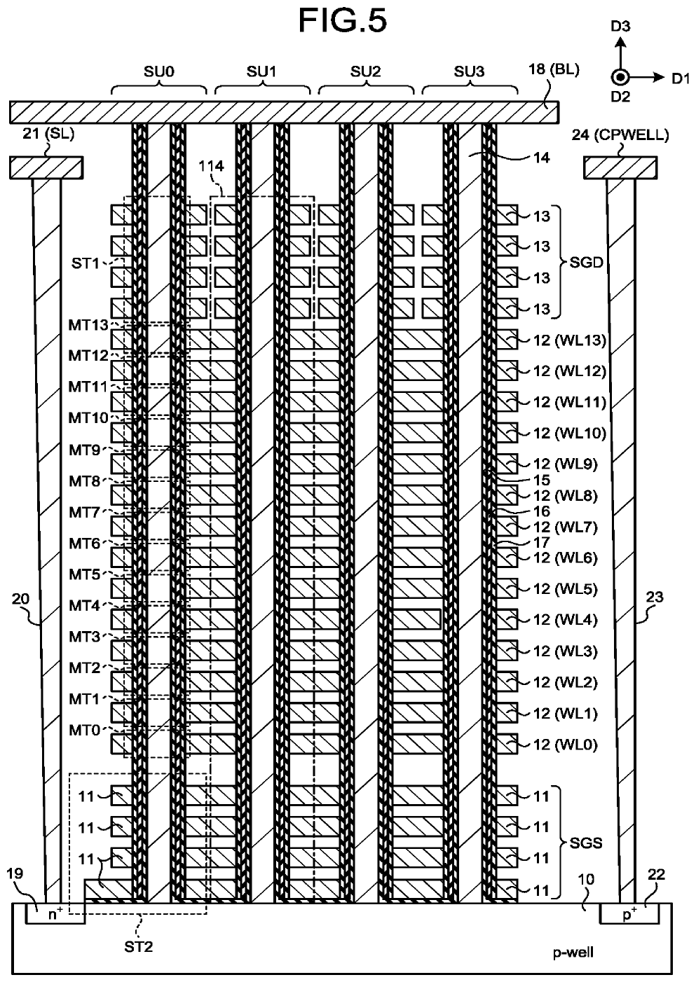

FIG. 5 is a cross-sectional view of a partial region of the block BLK of the first embodiment. As illustrated in the drawing, the NAND strings 125 are formed on a p-type well region (semiconductor substrate) 10. That is, for example, four wiring layers 11 functioning as the select gate lines SGS, fourteen wiring layers 12 functioning as the word lines WL0 to WL13, and four wiring layers 13 functioning as the select gate lines SGD are sequentially laminated on the well region 10. An insulating film (not illustrated) is formed between the wiring layers.

The block BLK includes a pillar-shaped conductor 14 that reaches the well region 10 through the wiring layers 13, 12 and 11. A gate insulating film 15, a charge storage layer (an insulating film or a conductive film) 16, and a block insulating film 17 are sequentially formed on the side surface of the conductor 14, thereby forming the memory cell transistor MT and the select transistors ST1 and ST2. The conductor 14 functions as a current path of the NAND string 125, and a region in which a channel of each transistor is formed. The top end of the conductor 14 is connected to a metal wiring layer 18 functioning as the bit line BL.

A surface region of the well region 10 includes an n+ type impurity diffusion layer 19. A contact plug 20 is attached to the diffusion layer 19, and connected to a metal wiring layer 21 functioning as the source line SL. The surface region of the well region 10 further includes a p+ type impurity diffusion layer 22. A contact plug 23 is attached to the diffusion layer 22, and connected to a metal wiring layer 24 functioning as a well wiring CPWELL. The well wiring CPWELL is a wiring for applying a potential to the conductor 14 through the well region 10.

The above multiple elements are arranged in a second direction D2 parallel to the semiconductor substrate, and a set of the NAND strings 125 arranged in the second direction D2 form the string unit SU.

Hereinafter, the memory cell transistor MT will be referred to as a memory cell.

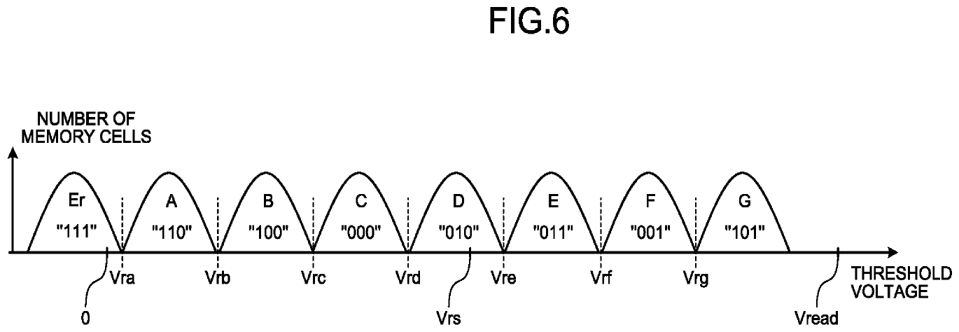

FIG. 6 is a graph illustrating an example of a possible threshold voltage of the memory cell of the first embodiment. The vertical axis represents the number of memory cells, and the horizontal axis represents the threshold voltage. In the following, the present embodiment will describe an example that each memory cell can hold 8-value data. However, holdable data is not limited to eight values. In the present embodiment, the memory cell can hold binary data or more, i.e., 1-bit data or more.

As illustrated in FIG. 6, a possible threshold voltage range is divided into eight ranges. These eight divisions will be referred to as an “Er” state, an “A” state, a “B” state, a “C” state, a “D” state, an “E” state, an “F” state, and a “G” state in ascending order of the threshold voltage. The threshold voltage of each memory cell is controlled by the processing circuit 110 to be in any of the “Er” state, the “A” state, the “B” state, the “C” state, the “D” state, the “E” state, the “F” state, and the “G” state. As a result, in the case of plotting the number of memory cells with the threshold voltage as the horizontal axis, the memory cell exhibits eight distributions in eight different states, as illustrated in FIG. 6.

The eight states correspond to three bits of data. According to the example in the drawing, the “Er” state corresponds to data “111”, the “A” state corresponds to data “110”, and the “B” state corresponds to data “100”, the “C” state corresponds to data “000”, the “D” state corresponds to data “010”, the “E” state corresponds to data “011”, the “F” state corresponds to data “001”, and the “G” state corresponds to data “101”. In the drawing, the most significant bit (MSB) is arranged at the left end and the least significant bit (LSB) is arranged at the right end.

Thus, each memory cell can hold data according to the state of the threshold voltage. The correspondence illustrated in FIG. 6 is an example of data coding. The data coding is not limited to the example in FIG. 6.

Among the 3-bit data held in one memory cell, the LSB will be referred to as a lower bit, the MSB will be referred to as an upper bit, and a bit between the LSB and the MSB will be referred to as a middle bit. A set of lower bits of all the memory cell transistors MT of the same memory cell group MCG will be referred to as a lower page. A set of middle bits of all the memory cell transistors MT of the same memory cell group MCG will be referred to as a middle page. A set of upper bits of all the memory cell transistors MT of the same memory cell group MCG will be referred to as an upper page.

The threshold voltage is lowered to the “Er” state through the erase operation. The threshold voltage is maintained in the “Er” state or raised to any of the “A” state, the “B” state, the “C” state, the “D” state, the “E” state, the “F” state, and the “G” state through the program operation.

Specifically, the sense amplifier 122 selects the bit line BL corresponding to the column address in the program operation. The row decoder 124 selects the word line WL corresponding to the row address, and repeatedly applies a program voltage and a verify voltage to the selected word line WL by increment of the program voltage value by ΔVprog. Then, a charge is injected into a charge storage layer 16 of the memory cell located at an intersection between the selected bit line BL and the selected word line WL, increasing the threshold voltage of the memory cell. The sense amplifier 122 performs a read operation at given timing to check whether the threshold voltage of the memory cell has reached a target state corresponding to data (verify read). The sequencer 114 repeatedly applies the voltage Vprog until the threshold voltage of the memory cell reaches the target state.

Hereinafter, a memory cell whose threshold voltage is set to a certain state by a program operation may be referred to as a memory cell in the state.

A determination voltage is set between two adjacent states. For example, a determination voltage Vra is set between the “Er” state and the “A” state, a determination voltage Vrb is set between the A “state and the” B “state, a determination voltage Vrc is set between the “B” state and the “C” state, a determination voltage Vrd is set between the “C” state and the “D” state, a determination voltage Vre is set between the “D” state and the “E” state, a determination voltage Vrf is set between the “E” state and the “F” state, and a determination voltage Vrg is set between the “F” state and the “G” state as illustrated in FIG. 6. In the read operation, data corresponding to a state of a memory cell is determined by a plurality of determination voltages.

For example, consider that the data coding illustrated in FIG. 6 is applied. When a memory cell is in any of the “Er” state, the “E” state, the “F” state, and the “G” state, a value of a lower bit held by the memory cell is “1”. When a memory cell is in any of the “A” state, the “B” state, the “C” state, and the “D” state, a value of a lower bit held by the memory cell is “0”. Thus, data of a lower page can be determined using two determination voltages Vra and Vre.

When a memory cell is in any of the “Er” state, the “A” state, the “D” state, and the “E” state, a value of a middle bit held by the memory cell is “1”. When a memory cell is in one of the “B” state, the “C” state, the “F” state, and the “G” state, a value of a middle bit held by the memory cell is “0”. Thus, data of a middle page can be determined using three determination voltages Vrb, Vrd, and Vrf.

When a memory cell is in any of the “Er” state, the “A” state, the “B” state, and the “G” state, a value of an upper bit held by the memory cell is “1”. When a memory cell is in one of the “C” state, the “D” state, the “E” state, and the “F” state, a value of an upper bit held by the memory cell is “0”. Thus, data of an upper page can be determined using two determination voltages Vrc and Vrg.

In this manner, the determination voltages used in data determination differ depending on the type of a page to read. In the read operation, the row decoder 124 uses a plurality of determination voltages corresponding to a type of a page to read.

More specifically, the sense amplifier 122 pre-charges a power supply voltage VDD to the bit line BL in the read operation. The row decoder 124 selects a word line WL corresponding to a row address, that is, the word line WL connected to a memory cell being a read target. The row decoder 124 applies a voltage Vread to an unselected word line WL, that is, the word line WL connected to a memory cell being a non-read target. The voltage Vread is set to a value higher than that of the “G” state as illustrated in FIG. 6. By applying the voltage Vread to the unselected word line WL, each memory cell connected to the unselected word line WL becomes conductive regardless of the state of the threshold voltage. The row decoder 124 sequentially applies different determination voltages corresponding to the type of a page to read to the selected word line WL. The sense amplifier 122 identifies a determination voltage that has caused the outflow of the charge stored by pre-charging to the source line SL, thereby determining data corresponding to the state of the target memory cell.

Meanwhile, the charge stored in the charge storage layer 16 leaks over time. A leakage path includes a path to the conductor 14 through the gate insulating film 15, a path to the wiring layer 12 through the block insulating film 17, or a path toward an adjacent memory cell through the charge storage layer 16. The threshold voltage of the memory cell decreases due to the leakage of the charge from the charge storage layer 16. If the threshold voltage exceeds a state boundary due to the decrease of the threshold voltage, a phenomenon that data different from data at the time of the program operation is read by the read operation occurs. A changed data bit may be referred to as a bit error.

As described above, a period from storage of data to such a change in data is referred to as data retention. It is preferable to elongate the data retention as much as possible.

For example, changed data or a bit error is normally corrected to correct data by the error correction function of the memory controller 200. However, there is an upper limit to the performance of the error correction function. Data stored in each block BLK is corrected to correct data by the error correction function before the number of bit errors exceeds the number correctable by the error correction function, and is then relocated to another block BLK. This process is referred to as refresh operation.

A short data retention time results in increasing a refresh frequency, which degrades the performance of the memory system 1. The extension of the data retention can thus lower the refresh frequency, and prevent the performance degradation of the memory system 1 accompanying the refresh operation.

In some case, the memory controller 200 periodically reads data from each block BLK in order to check whether refresh operation is necessary. This process is referred to as patrol read operation. The extension of the data retention can lower the refresh frequency, and prevent the performance degradation of the memory system 1 system 1 accompanying the patrol read operation.

In the first embodiment, the memory cell array 121 can be controlled to be in a retention-stand-by (RS) state during execution of no access, that is, no program, read, and erase operations. In the RS state, a given voltage is continuously applied to a word line group. This can avoid the leakage of the charge from the charge storage layer 16, leading to extending the data retention.

An applied voltage to the word line group in the RS state will be referred to as a voltage Vrs. A value of the voltage Vrs can be set optionally. However, a too high voltage Vrs causes a charge to be injected into the charge storage layer 16 rather than lowering the charge leakage, which causes change in data.

For example, by multiple read operations to a specific word line WL of a block BLK, the voltage Vread may be applied to another word line WL multiple times. In such a case, data may be changed in each memory cell connected to the word line WL to which the voltage Vread has been applied multiple times because of gradual charge injection into the charge storage layer 16 by the application of the voltage Vread. This phenomenon is known as read disturb.

Thus, the voltage Vrs can be to set a value higher than 0 V and lower than the voltage Vread. As a result, it is possible to extend the data retention while reducing the injection of the charge into the charge storage layer 16 as much as possible.

In FIG. 6 the voltage Vrs is set to a voltage value about half the voltage Vread as an example.

Hereinafter, a normal standby state in which no voltage Vrs is applied to the group of the word lines WL will be referred to as a normal standby (NS) state.

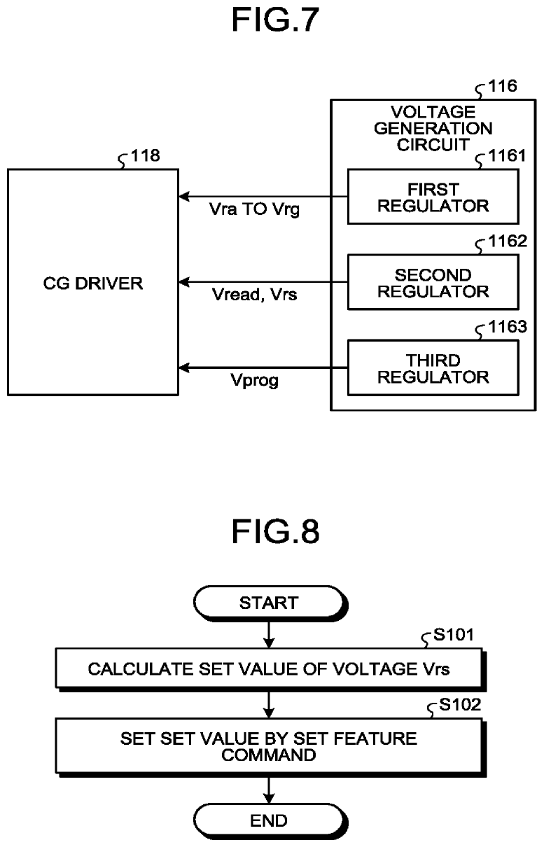

The voltage Vrs is generated by the voltage generation circuit 116. FIG. 7 is a schematic diagram illustrating an example of a configuration of the voltage generation circuit 116 of the first embodiment. As illustrated in the drawing, the voltage generation circuit 116 includes a first regulator 1161, a second regulator 1162, and a third regulator 1163.

The first regulator 1161 generates a voltage for the selected word line WL. That is, the first regulator 1161 generates the determination voltages Vra to Vrg.

The determination voltages Vra to Vrg can be dynamically adjusted by, for example, the memory controller 200. For example, if data obtained by the read operation contains the number of bit errors equal to or larger than a given value, part or all of the determination voltages Vra to Vrg are adjusted to perform the read operation again. Adjusting part or all of the determination voltages Vra to Vrg to execute the read operation is referred to as shift read.

The first regulator 1161 is configured to be able to adjust an output voltage with finer granularity than another regulator (for example, the second regulator 1162) in order to deal with the shift read.

The second regulator 1162 generates a voltage for the unselected word line WL. That is, the second regulator 1162 generates the voltage Vread.

In the read operation and the program operation, one word line WL is selected and the rest of the word lines WL are not selected from a target block BLK. Thus, to boost the unselected word lines WL, a larger current is to be supplied thereto than to the selected word line WL.

In view of this, the second regulator 1162 has a higher capacity to supply the current than the first regulator 1161. As a result, the second regulator 1162 can boost a large number of word lines WL arranged in a wide area to the voltage Vread at a higher speed.

The second regulator 1162 can further generate the voltage Vrs. Thus, the second regulator 1162 can apply the voltage Vrs to the large number of word lines WL arranged in a wide area.

The third regulator 1163 can generate the voltage Vprog. The voltage Vprog is higher than the voltage Vread. This enables quick injection of a charge into the charge storage layer 16.

The CG driver 118 applies various internal voltages generated by the first regulator 1161, the second regulator 1162, and the third regulator 1163 to the corresponding one or more word lines WL.

Referring back to FIG. 1, the respective elements of the memory controller 200 execute the control of the entire memory system 1 in cooperation.

For example, the memory controller 200 transfers data between the host 2 and each of the memory chips 100. In response to receipt of a read request from the host 2, the memory controller 200 reads data from the memory chip 100 holding the data designated by the read request. Then, the memory controller 200 transmits the read data to the host 2. In response to a write request from the host 2, the memory controller 200 determines the memory chip 100 as a write destination of data received together with the write request and writes the data to the determined memory chip 100.

That is, the memory controller 200 accesses each of the memory chips 100 in response to a request from the host 2.

In addition, the memory controller 200 executes internal processing such as garbage collection, wear leveling, and the above-described refresh operation in addition to processing the request from the host 2.

As described above, data is erased from the memory cell array 121 in units of the blocks BLK. Meanwhile, data is read and written in units of pages smaller than the blocks BLK. Data is inerasable in a unit smaller than the block BLK, so that, to update old data with new data sent from host 2, the new data is not overwritten to the old data but written to a free region. After writing the new data, the old data in the memory cell array 121 is handled as invalid data. The new data in the memory cell array 121 is handled as valid data.

When the free space is used up, the memory controller 200 erases the invalid data from the block BLK in order to create a free space in the block BLK. However, it is rare that the entire data stored in one block BLK is invalid. Thus, the memory controller 200 relocates the valid data remaining in one block BLK to another block BLK. After the relocation of the valid data, the block BLK being a relocation source no longer includes valid data. The block BLK containing no valid data by the relocation is referred to as a free block. Data is collectively erased from the free block, and all the pages in the free block become free spaces. Relocating valid data between the blocks BLK in order to increase the number of free blocks is referred to as garbage collection.

In addition, a process from the first write operation and to the data erase operation on a free block BLK is referred to as a P (program)/E (erase) cycle. A characteristic of a memory cell transistor, such as the data retention, deteriorates as the number of P/E cycles increases. The memory controller 200 relocates data to equalize the number of P/E cycles. The relocation for equalization of the number of P/E cycles is referred to as wear leveling.

The memory controller 200 counts the number of P/E cycles, for example, for each block BLK. The memory controller 200 stores a count value of the P/E cycles as part of management information. Then, the memory controller 200 determines a block BLK as a transfer source and another block BLK as a transfer destination according to the count value of the P/E cycles for each block BLK, and relocates data from the source block BLK to the destination block BLK.

The memory controller 200 also accesses each of the memory chips 100 in the internal processing such as the garbage collection, the wear leveling, and the refresh operation.

Further, the memory controller 200 can cause the memory cell array 121 to transition to the RS state in units of the memory chips 100.

Specifically, upon satisfaction of a given condition (hereinafter referred to as a transition condition), the memory controller 200 transmits an RS entry command to the memory chip 100 which the processing circuit 110 is not accessing, i.e., executing no program, read, and erase operations.

To resume accessing the memory chip 100 including the memory cell array 121 maintained in the RS state, the memory controller 200 transmits an RS exit command to the memory chip 100.

The transition condition is optionally set. The following describes three exemplary transition conditions.

A first example is such that whether the memory cell array 121 can transition to the RS state is determined in accordance with temperature.

Typically, the higher the temperature of a memory cell is, the shorter the data retention is. In the RS state, however, power consumption increases because the voltage is continuously applied to the word line group. Thus, for example, at a lower temperature of the memory cell than a given value, the memory cell is enabled to transition to the RS state. At a higher temperature of the memory cell than the given value, the memory cell is prohibited from transitioning to the RS state. Thereby, by controlling the transition of the memory cell array 121 to the RS state, it is possible to avoid the data retention from shortening. This enables the extension of the data retention while avoiding the increase in power consumption as much as possible.

A second example is such that whether the memory cell array 121 can transition to the RS state is determined in accordance with receipt or non-receipt of a request for a low power consumption mode from the host 2.

The low power consumption mode refers to a mode in which the memory system 1 consumes less power than in a normal operation mode (hereinafter referred to as a normal mode). In other words, the low power consumption mode is required to reduce power consumption from that in the normal mode by powering off at least part of the respective elements of the memory chip 100 or the respective elements of the memory controller 200. However, the memory cell array 121 in the RS state consumes a larger amount of power consumption. It is thus difficult to achieve lower power consumption.

In view of this, the memory cell is enabled to transition to the RS state in the normal mode, and prohibited from transitioning to the RS state in the low power consumption mode. This makes it possible to reduce the power consumption in response to the low power consumption mode request.

A third example is such that whether the memory cell array 121 can transition to the RS state is determined in accordance with the number of P/E cycles.

The data retention is likely to shorten as the number of P/E cycles increases. Thus, for example, if the number of P/E cycles is larger than a given value, the memory cell is enabled to transition to the RS state and prohibited from transitioning to the RS state if the number of P/E cycles is smaller than the given value. Thereby, the memory cell array 121 can be controlled to be in the RS state only in a period for which the data retention is likely to shorten. This makes it possible to extend the data retention while avoiding the increase in power consumption as much as possible.

In the first embodiment, the transition condition is set to a combination of the determination condition based on the temperature, the determination condition based on the operation mode, and the determination condition based on the number of P/E cycles, as one example.

The transition condition may be set to part of the determination condition based on the temperature, the determination condition based on the operation mode, and the determination condition based on the number of P/E cycles. The transition condition may be set to a determination condition different from these determination conditions. Alternatively, with no transition condition set, the memory controller 200 may be configured to transmit the RS entry command on the basis of whether the memory chip 100 is executing the access.

The memory controller 200 can set a value of the voltage Vrs. As an example, the voltage Vrs is set by a set feature command. An exemplary setting method of the value of the voltage Vrs will be described later.

The value of the voltage Vrs may be set to each of the memory chips 100 before shipping and fixed to the initial value during the operation of the memory system 1. That is, the memory controller 200 does not necessarily have the function of setting the value of the voltage Vrs.

The memory controller 200 can be configured of software, hardware, or a combination thereof. The memory controller 200 may be configured as one system-on-a-chip (SoC) or include a plurality of chips. According to the example illustrated in FIG. 1, the memory controller 200 has a hardware configuration including a host interface 210, a memory interface 220, a RAM 230, a processor 240, and a temperature sensor 250.

The host interface 210 manages communications between the memory controller 200 and the host 2.

The memory interface 220 is connected to each of the memory chips 100 via a channel, and manages communications between the memory controller 200 and the memory chip 100.

The processor 240 controls the operation of the memory controller 200. For example, the processor 240 analyzes a request from the host 2, controls access to each of the memory chips 100 in response to the request from the host 2, and controls internal processing.

The processor 240 may be, for example, a circuit such as a central processing unit (CPU) that operates by a firmware program. The processor 240 may also be a circuit that requires no program to operate, such as a field-programmable gate array (FPGA) and an application specific integrated circuit (ASIC). The processor 240 may include a combination of the circuit that operates by the firmware program and the circuit that requires no program to operate.

The RAM 230 can be used as a buffer for data transfer between the host 2 and each of the memory chips 100. In addition, the RAM 230 can be used as a memory in which data and various types of management information are cached.

The temperature sensor 250 detects a temperature inside the memory system 1. A value detected by the temperature sensor 250 is used to determine the transition condition.

The memory system 1 includes parts or components, such as the memory chip 100, that generate heat during operation. The temperature inside the memory system 1 increases or decreases depending on the degree of heat generation from such parts or components and an ambient temperature of the memory system 1. If the temperature inside the memory system 1 exceeds a given value, the memory system 1 does not operate properly or malfunctions. Thus, at a too high temperature of the memory system 1, the memory controller 200 intentionally lowers the performance of the memory system 1 in order to reduce the amount of heat generation. Such control to intentionally lower the performance of the memory system 1 according to the temperature of the memory system 1 is referred to as thermal throttling.

The memory system 1 includes a temperature sensor used in the thermal throttling. The temperature sensor 250 of the embodiment may or may not be used for the thermal throttling. In addition, the temperature sensor 250 may be located outside the memory controller 200. The temperature sensor 250 may be incorporated in one or both of the two memory chips 100. The number of temperature sensors 250 in the memory system 1 is not limited to one.

Subsequently, the operation of the memory system 1 of the first embodiment will be described. The memory controller 200 performs the same control individually over the memory chip 100-0 and the memory chip 100-1. In the following, one of the memory chip 100-0 and the memory chip 100-1 will be referred to as a target memory chip 100, and a control over the target memory chip 100 will be described.

FIG. 8 is a flowchart illustrating an operation of setting the voltage Vrs by the memory controller 200 of the first embodiment.

First, the memory controller 200 calculates a set value of the voltage Vrs (S101).

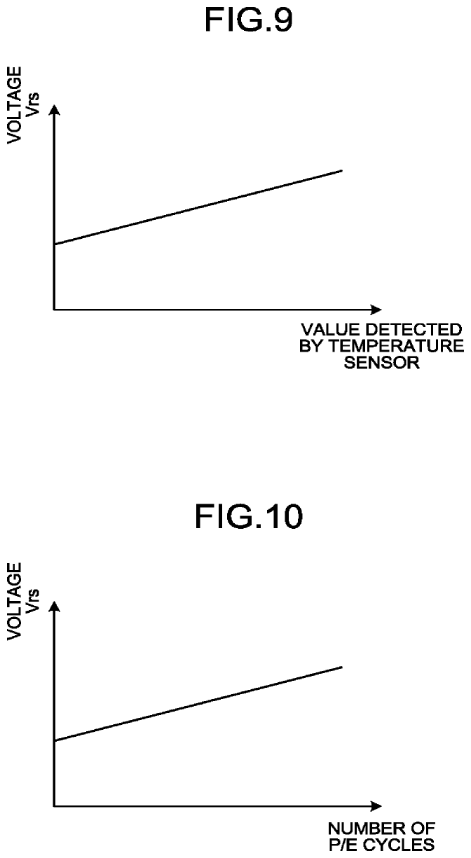

A method of calculating the set value is optional. For example, the memory controller 200 may set a higher value to the voltage Vrs as the value detected by the temperature sensor 250 is higher as illustrated in FIG. 9. For another example, the value of the voltage Vrs may be increased as the number of P/E cycles increases as illustrated in FIG. 10.

Subsequent to S101, the memory controller 200 transmits a set feature command including the set value to the target memory controller 200 (S102). In the target memory chip 100, the sequencer 114 stores the set value transmitted by the set feature command in its own register (not illustrated).

The operation of setting the voltage Vrs ends in S102.

For example, the memory controller 200 performs the above operation only once before transmitting an RS entry command to the memory chip 100. Alternatively, the memory controller 200 performs the above operation at given time intervals. Alternatively, the memory controller 200 performs the above operation at timing when an optional quantity, such as the value detected by the temperature sensor 250 and the number of P/E cycles, satisfies a given condition. That is, the memory controller 200 can perform the operation of setting the voltage Vrs at optional timing.

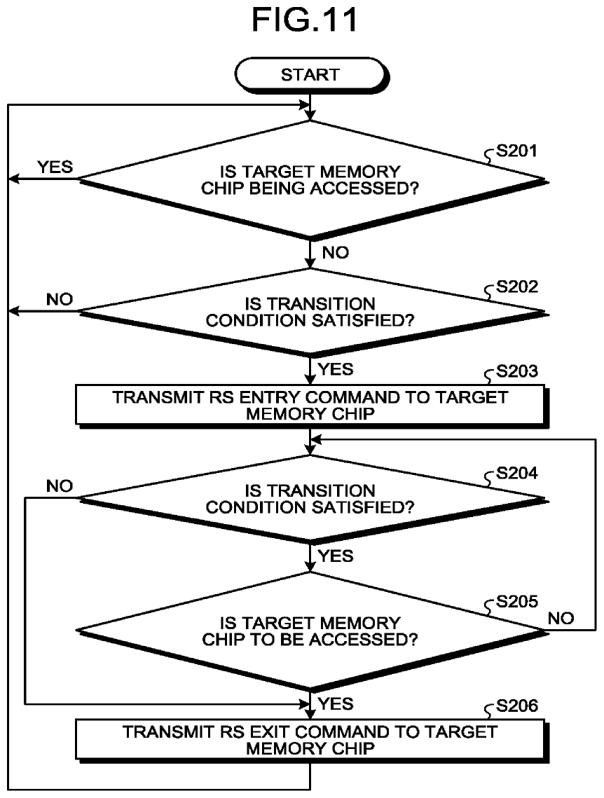

FIG. 11 is a flowchart illustrating an exemplary control method of the memory chip 100 by the memory controller 200 of the first embodiment.

First, the memory controller 200 determines whether the target memory chip 100 is being accessed (S201). In S201, the access refers to writing data to the target memory chip 100, reading data from the target memory chip 100, or erasing data from the target memory chip 100 by transmitting a program command, a read command, or an erase command to the target memory chip 100.

If the target memory chip 100 is being accessed (Yes in S201), the memory controller 200 executes the determination in S201 again. If the target memory chip 100 is not being accessed (No in S201), the memory controller 200 determines whether the transition condition is satisfied (S202).

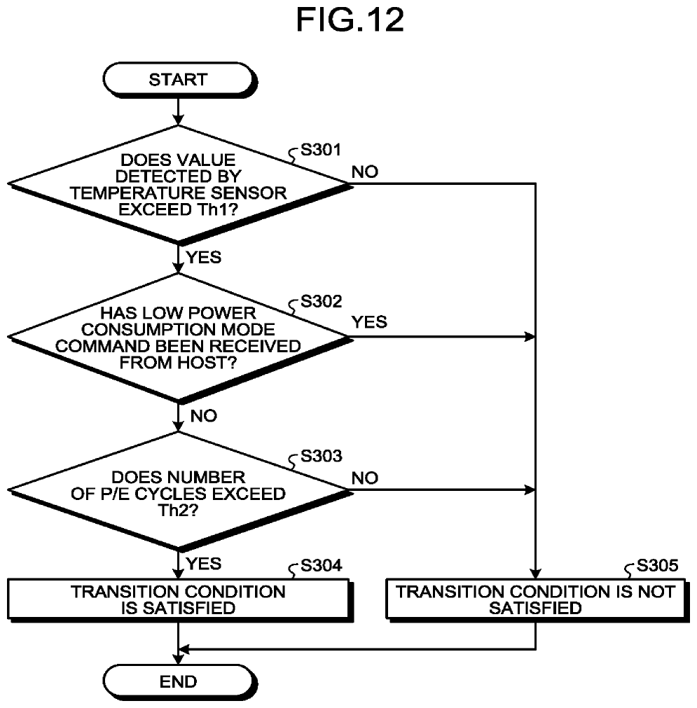

FIG. 12 is a flowchart illustrating an example of the operation in S202, that is, determining whether the transition condition is satisfied. The operation illustrated in FIG. 12 is also executed in S204 to be described later.

First, the memory controller 200 determines whether the value detected by the temperature sensor 250 exceeds a given threshold Th1 (S301).

For example, the processor 240 acquires detected values from the temperature sensor 250 at certain short time intervals. The processor 240 compares the latest detected value with the threshold Th1. The timing at which the detected value is acquired from the temperature sensor 250 is not limited thereto. The processor 240 may acquire the detected value from the temperature sensor 250 at the time of performing S201.

If the value detected by the temperature sensor 250 exceeds the threshold Th1 (Yes in S301), the memory controller 200 determines whether the low power consumption mode request has been received from the host 2 (S302).

If the memory system 1 is to transit from the normal mode to the low power consumption mode in response to the low power consumption mode request from the host 2, the memory controller 200 determines that the low power consumption mode request has been received from the host 2. If the memory system 1 is in the low power consumption mode, the memory controller 200 determines that the low power consumption mode request has been received from the host 2. In the case of no receipt of the low power consumption mode request since the normal mode, the memory controller 200 determines no receipt of the low power consumption mode request from the host 2.

With no receipt of the low power consumption mode request from the host 2 (No in S302), the memory controller 200 determines whether the number of P/E cycles exceeds a given threshold Th2 (S303).

As described above, the memory controller 200 counts the number of P/E cycles for each block BLK, and stores the count value as part of the management information. The memory controller 200 executes the operation in S203 in accordance with the count value of the number of P/E cycles for each block BLK stored as the management information.

For example, the memory controller 200 compares a representative value of the count values for all the blocks BLK of the target memory chip 100 with the threshold Th2. The representative value may be, for example, an average value, a median value, or an integrated value.

The memory controller 200 controls the number of P/E cycles to be as uniform as possible in all the blocks BLK by wear leveling. Thus, one block BLK may be selected from the blocks BLK of the memory chip 100-0 or the memory chip 100-1 by any method, to compare a count value of the selected block BLK with the threshold Th2.

When the number of P/E cycles exceeds the given threshold Th2 (Yes in S303), the memory controller 200 determines that the transition condition is satisfied (S304), completing the determination on whether the transition condition is satisfied.

When the value detected by the temperature sensor 250 does not exceed the given value (No in S301), when the low power consumption mode request has been received from the host 2 (Yes in S302), or when the number of P/E cycles does not exceed the given threshold Th2 (No in S303), the memory controller 200 determines that the transition condition is not satisfied (S305), completing the determination on whether the transition condition is satisfied.

The above operation is an exemplary operation for determining whether the transition condition is satisfied. Satisfaction or non-satisfaction of the transition condition can be determined by any method.

Referring back to FIG. 11, upon satisfaction of the transition condition (Yes in S202), the memory controller 200 transmits an RS entry command to the target memory chip 100 (S203).

In response to the target memory chip 100's receiving the RS entry command, the sequencer 114 of the target memory chip 100 causes the second regulator 1162 to generate the voltage Vrs being a voltage of a set value stored in the register. The respective row decoders 124 apply the voltages Vrs generated by the second regulators 1162 to all the word lines of the respective planes 120. As a result, each of the memory cell arrays 121 transitions from the NS state to the RS state.

After S203, the memory controller 200 repeatedly determines on whether the transition condition is satisfied (S204) and on whether to access the target memory chip 100 (S205). That is, upon satisfaction of the transition condition (Yes in S204) and if the target memory chip 100 is not to be accessed after lastly accessed (No in S205), the memory controller 200 executes the operations in S204 and S205 again.

Upon non-satisfaction of the transition condition (No in S204) or if the target memory chip is to be accessed (Yes in S205), the memory controller 200 transmits an RS exit command to the target memory chip (S206). In response to the target memory chip 100's receiving the RS exit command, the sequencer 114 causes the second regulator 1162 to stop generating the voltage Vrs. As a result, each of the memory cell arrays 121 transitions from the RS state to the NS state.

After S206, the memory controller 200 executes the operation in S201.

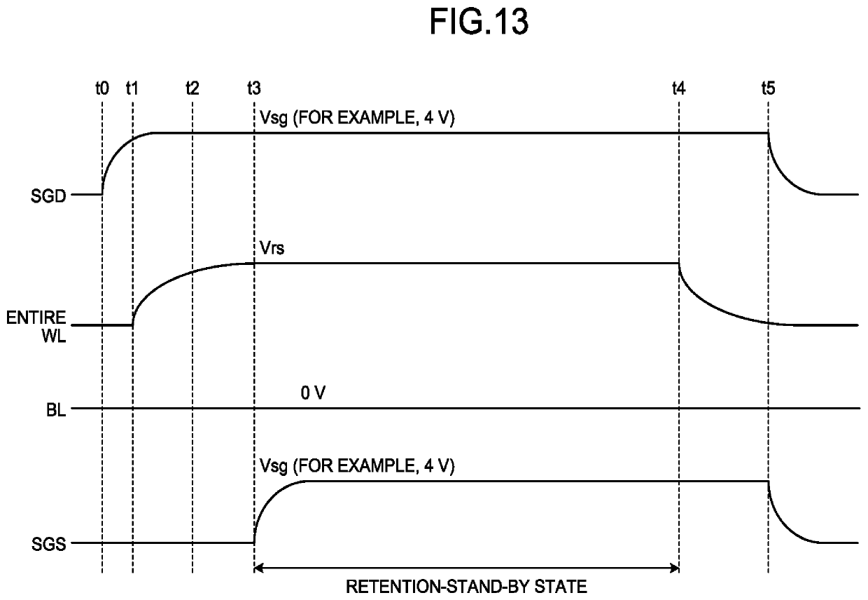

FIG. 13 illustrates an example of a waveform of a voltage applied to each element in the RS state in the first embodiment.

In response to the memory chip 100's receiving an RS entry command, the sequencer 114 of the memory chip 100 starts applying the voltage Vsg to the select gate line SGD (time t0). Subsequently, the sequencer 114 starts applying the voltage Vrs to all the word lines WL (time t1). The sequencer 114 starts applying the voltage Vsg to the select gate line SGS (time t3). As a result, the memory cell array 121 is turned into the RS state.

A value of the voltage Vsg is set to 4 V, for example. The value of the voltage Vsg is not limited thereto.

In response to the memory chip 100's receiving an RS exit command, the sequencer 114 ends applying the voltage Vrs to all the word lines WL (time t4). As a result, the memory cell array 121 transitions from the RS state to the NS state. Subsequently, the sequencer 114 ends applying the voltage Vsg to the select gate lines SGD and SGS (time t5).

The waveforms illustrated in FIG. 13 are merely exemplary. The voltage-application start timing and end timing are not limited to the examples illustrated in FIG. 13.

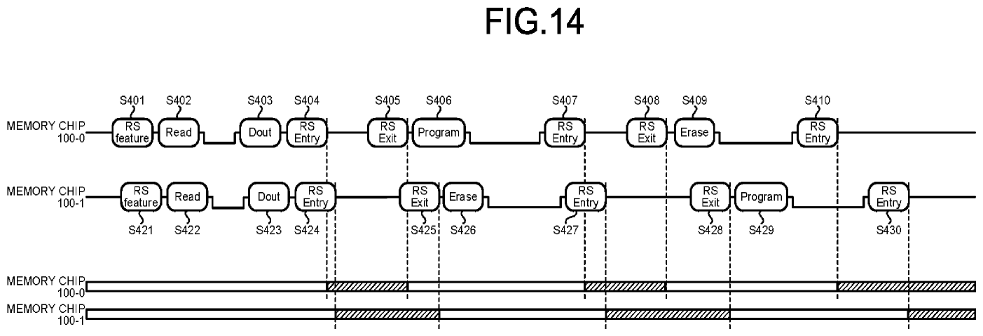

FIG. 14 illustrates exemplary timing charts of transmission and reception of information between the memory controller 200 and each of the memory chips 100 and a diagram of state transition of the memory cell array 121 in the first embodiment. FIG. 14 depicts a timing chart of transmission and reception of information between the memory controller 200 and the memory chip 100-0, a timing chart of transmission and reception of information between the memory controller 200 and the memory chip 100-1, a diagram illustrating a state of the memory cell array 121 of the memory chip 100-0, and a diagram illustrating a state of the memory cell array 121 of the memory chip 100-1 in this order from the top to the bottom.

The respective timing charts illustrate a state of the IO signal line and a state of an Ry/By signal line in an overlapping manner.

In the diagrams of the states of the respective memory cell arrays 121, a period in which the memory cell array 121 is placed in the RS state is indicated by a hatched bar. A period in which the memory cell array 121 is placed in the NS state is indicated by a white bar.

According to the example of FIG. 14, the memory controller 200 first transmits a set feature command for setting the voltage Vrs to the memory chip 100-0 (S401). Subsequently, the memory controller 200 transmits a read command (S402), and the processing circuit 110 of the memory chip 100-0 executes a read operation in response to the read command. During the read operation, the Ry/By signal line is maintained in a busy state. After completion of the read operation, the memory controller 200 acquires data from the memory chip 100-0 (S403). The data acquiring operation from the memory chip 100 is denoted by Dout in FIG. 14.

After acquiring the data, the memory controller 200 transmits an RS entry command (S404). The processing circuit 110 of the memory chip 100-0 causes the two memory cell arrays 121 of the memory chip 100-0 to transition from the NS state to the RS state in response to the RS entry command.

Subsequently, the memory controller 200 transmits an RS exit command (S405). The processing circuit 110 of the memory chip 100-0 causes the two memory cell arrays 121 of the memory chip 100-0 to transition from the RS state to the NS state in response to the RS exit command.

After transmitting the RS exit command, the memory controller 200 transmits a program command (S406). The processing circuit 110 of the memory chip 100-0 executes a program operation in response to the program command. During the program operation, the Ry/By signal line is maintained in the busy state.

After completion of the program operation, the memory controller 200 transmits an RS entry command (S407). The processing circuit 110 of the memory chip 100-0 causes the two memory cell arrays 121 of the memory chip 100-0 to transition from the NS state to the RS state in response to the RS entry command.

Subsequently, the memory controller 200 transmits an RS exit command (S408). The processing circuit 110 of the memory chip 100-0 causes the two memory cell arrays 121 of the memory chip 100-0 to transition from the RS state to the NS state in response to the RS exit command.

After transmitting the RS exit command, the memory controller 200 transmits an erase command (S409). The processing circuit 110 of the memory chip 100-0 executes an erase operation in response to the erase command. During the erase operation, the Ry/By signal line is maintained in the busy state.

After completion of the erase operation, the memory controller 200 transmits an RS entry command (S410). The processing circuit 110 of the memory chip 100-0 causes the two memory cell arrays 121 of the memory chip 100-0 to transition from the NS state to the RS state in response to the RS entry command.

The memory controller 200 first transmits a set feature command for setting the voltage Vrs to the memory chip 100-1 (S421). Subsequently, the memory controller 200 transmits a read command (S422), and the processing circuit 110 of the memory chip 100-1 executes a read operation in response to the read command. During the read operation, the Ry/By signal line is maintained in a busy state. After completion of the read operation, the memory controller 200 acquires data from the memory chip 100-1 (S423).

After acquiring the data, the memory controller 200 transmits an RS entry command (S424). The processing circuit 110 of the memory chip 100-1 causes the two memory cell arrays 121 of the memory chip 100-1 to transition from the NS state to the RS state in response to the RS entry command.

Subsequently, the memory controller 200 transmits an RS exit command (S425). In the memory chip 100-1, the processing circuit 110 causes the two memory cell arrays 121 of the memory chip 100-1 to transition from the RS state to the NS state in response to the RS exit command.

After transmitting the RS exit command, the memory controller 200 transmits an erase command (S426). The processing circuit 110 of the memory chip 100-1 executes an erase operation in response to the erase command. During the erase operation, the Ry/By signal line is maintained in a busy state.

After completion of the erase operation, the memory controller 200 transmits an RS entry command (S427). The processing circuit 110 of the memory chip 100-1 causes the two memory cell arrays 121 of the memory chip 100-1 to transition from the NS state to the RS state in response to the RS entry command.

Subsequently, the memory controller 200 transmits an RS exit command (S428). The processing circuit 110 of the memory chip 100-1 causes the two memory cell arrays 121 of the memory chip 100-1 to transition from the RS state to the NS state in response to the RS exit command.

After transmitting the RS exit command, the memory controller 200 transmits a program command (S429). The processing circuit 110 of the memory chip 100-1 executes an erase operation in response to the program command. During the program operation, the Ry/By signal line is maintained in a busy state.

After completion of the program operation, the memory controller 200 transmits an RS entry command (S430). The processing circuit 110 of the memory chip 100-1 causes the two memory cell arrays 121 of the memory chip 100-1 to transition from the NS state to the RS state in response to the RS entry command.

In this manner, the memory controller 200 can asynchronously transmit various commands including the RS entry command and the RS exit command to each of the memory chips 100. As a result, the memory controller 200 can control the memory cell array 121 to transition between the states in units of the memory chips 100.

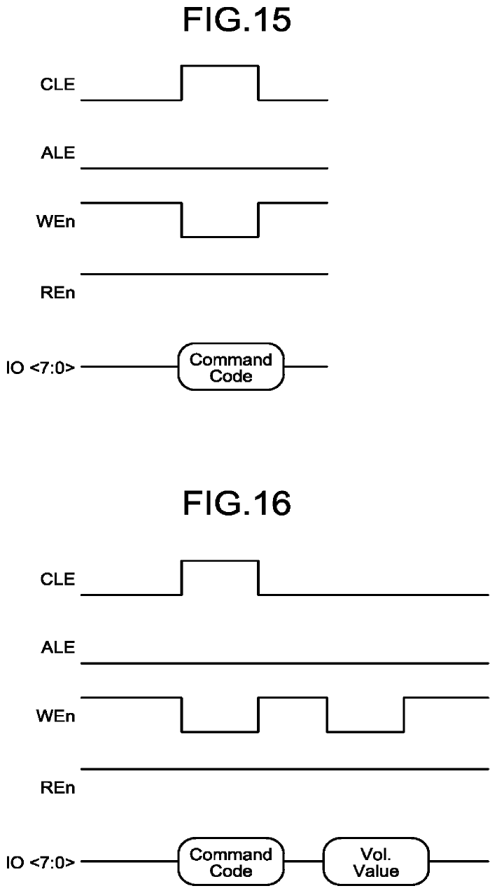

FIG. 15 is a diagram illustrating an example of state transition of various signal lines in transmitting the RS entry command and the RS exit command according to the first embodiment. FIG. 16 illustrates an example of state transition of various signal lines in transmitting the set feature command for setting the voltage Vrs according to the first embodiment.

In the examples illustrated in FIGS. 15 and 16, the CLE signal and the ALE signal make a positive logic transition, and the WE signal and the RE signal make a negative logic transition. The IO signal has a bit width of 8 bits as an example. The logic of the transition of each signal is not limited to the above logic. The bit width of the IO signal is not limited to the above bit width.

As illustrated in FIG. 15, a command code indicating an RS entry command or an RS exit command is transferred to the IO signal line at the time of transmitting the RS entry command and the RS exit command. While the command code is being transferred, the CLE signal is maintained in a HIGH state, and the WE signal is maintained in a LOW state. While no command is being transferred, the CLE signal and the ALE signal are maintained in a LOW state, and the WE signal and the RE signal are maintained in a HIGH state. The states of the ALE signal and the RE signal do not change regardless of transmission or non-transmission of the command code to the IO signal line.

In the period for which the CLE signal is maintained in a HIGH state, the command user interface 112 acquires information transferred to the IO signal line as a command.

For the set feature command for setting the voltage Vrs as illustrated in FIG. 16, a command code indicating the set feature command and a set value (Vol. Value) of the voltage Vrs are transferred to the IO signal line. While the command code is being transferred, the CLE signal is maintained in the HIGH state, and the WE signal is maintained in the LOW state. While the set value of the voltage Vrs is being transferred, the CLE signal and the WE signal are maintained in the LOW state. While the command code or the set value of voltage Vrs is not being transferred, the CLE signal and the ALE signal are maintained in the LOW state, and the WE signal and the RE signal are maintained in the HIGH state. The states of the ALE signal and the RE signal do not change regardless of transmission or non-transmission of the command code or the set value of the voltage Vrs to the IO signal line.

In the period for which the CLE signal is maintained in the HIGH state and the WE signal is maintained in the LOW state, the command user interface 112 acquires the command code transferred to the IO signal line. In the period for which both the CLE signal and the ALE signal are maintained in the LOW state, and the WE signal is maintained in the LOW state, the command user interface 112 acquires the set value of the voltage Vrs transferred to the IO signal line.

As described above, the memory controller 200 causes the processing circuit 110 of the memory chip 100 to execute an access (first access) to the memory cell array 121 in the first embodiment. After completion of the first access to memory cell array 121, the memory controller 200 transmits the RS entry command to the memory chip 100, and transmits the RS exit command to the memory chip 100 before causing the processing circuit 110 to execute a second access subsequent to the first access. The processing circuit 110 starts applying the voltage Vrs to the word lines WL in the memory cell array 121 in response to the RS entry command, and ends applying the voltage Vrs to the word lines WL in the memory cell array 121 in response to the RS exit command.

Applying the voltage Vrs to the word lines WL can avoid the leakage of charge from the charge storage layer 16 of each of the memory cells connected to the word lines WL, which enables the extension of the data retention.

In addition, the processing circuit 110 is configured to be able to execute a read operation. In the read operation, the processing circuit 110 applies the determination voltages (Vra to Vrg) to the selected word line WL, that is, the word line WL connected to the memory cell being a read target, and applies the voltage Vread to turn on the memory cell to the unselected word line WL, that is, the word line WL connected to the memory cell being a non-read target. The voltage Vrs is lower than the voltage Vread.

Thereby, it is made possible to extend the data retention while decreasing the injection of the charge into the charge storage layer 16 as much as possible.

The processing circuit 110 includes the first regulator 1161 configured to generate the determination voltage, and the second regulator 1162 configured to generate the voltage Vread and the voltage Vrs.

The memory system 1 further includes the temperature sensor 250. The memory controller 200 determines whether to transmit the RS entry command in accordance with the value detected by the temperature sensor 250.

This can avoid the increase in power consumption, as compared with the memory controller 200 configured to transmit the RS entry command with no exception after completion of accessing the memory cell array 121.

In addition, the memory controller 200 determines whether to transmit the RS entry command in accordance with receipt or non-receipt of the low power consumption mode request from the host 2.

This makes it possible to reduce the power consumption in response to the low power consumption mode request.

In addition, the memory controller 200 counts the number of P/E cycles, and determines whether to transmit the RS entry command in accordance with the count value of the number of P/E cycles.

As a result, it is possible to avoid the increase in power consumption as compared with the memory controller 200 configured to transmit the RS entry command with no exception after completion of the access to the memory cell array 121.

In addition, the memory controller 200 transmits the set feature command for setting the voltage Vrs, and the processing circuit 110 applies the voltage Vrs of the value set by the set feature command.

Thereby, the memory controller 200 can change the value of voltage Vrs depending on a situation.

The above embodiment has described the example that the set feature command is used in setting the value of the voltage Vrs. The command used in setting the value of voltage Vrs is not limited thereto. A dedicated command for setting the value of the voltage Vrs may be prepared. The set value of the voltage Vrs may be transferred, as an argument of the RS entry command.

In addition, the memory controller 200 may calculate the set value of the voltage Vrs from the value detected by the temperature sensor 250, as described with reference to FIG. 9.

In addition, the memory controller 200 may calculate the set value of the voltage Vrs from the count value of the number of P/E cycles, as described with reference to FIG. 10.

A plurality of low power consumption modes associated with different priorities may be defined. The memory controller 200 may be configured to be able to transmit an RS entry command even when receiving the low power consumption mode request and to calculate a set value of the voltage Vrs in accordance with the priority.

For example, the higher the priority is, the lower the power consumption required is. The memory controller 200 calculates the set value of the voltage Vrs such that the higher the priority is, the lower the voltage Vrs is. Thereby, it is made possible to extend the data retention and achieve required lower power consumption at the same time.

### Second Embodiment

The first embodiment has described the example that the state transition of the memory cell array 121 is controlled in units of the memory chips 100. The unit of state transition of the memory cell array 121 is not limited to such unit. A second embodiment will describe an example that the state transition of the memory cell array 121 is controlled in units of the planes 120.

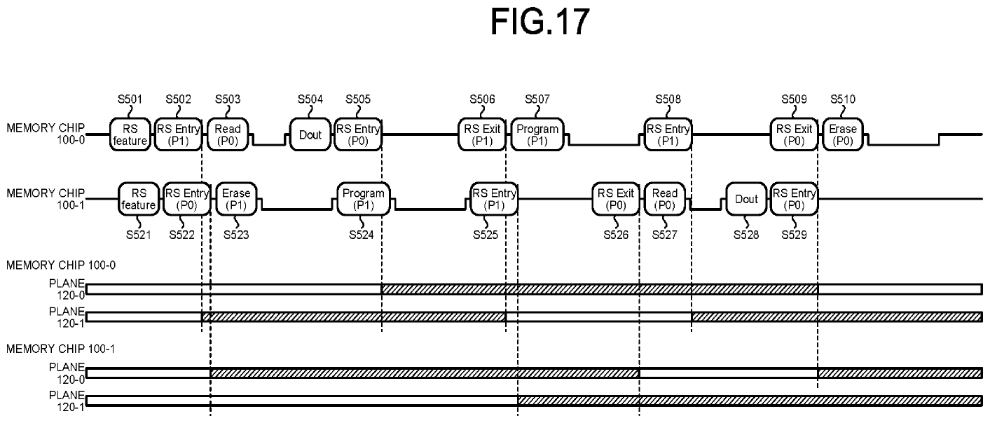

FIG. 17 illustrates an example of timing at which the memory controller 200 of the second embodiment transmits and receives information to and from each of the memory chips 100 and state transition timing of the memory cell array 121. FIG. 17 depicts a timing chart of transmission and reception of information between the memory controller 200 and the memory chip 100-0, a timing chart of transmission and reception of information between the memory controller 200 and the memory chip 100-1, a diagram illustrating the state of the memory cell array 121 of the plane 120-0 of the memory chip 100-0, a diagram illustrating a state of the memory cell array 121 of the plane 120-1 of the memory chip 100-0, a diagram illustrating a state of the memory cell array 121 of the plane 120-0 of the memory chip 100-1, and a diagram illustrating a state of the memory cell array 121 of the plane 120-1 of the memory chip 100-1 in this order from the top to the bottom.

The respective timing charts depict a state of the IO signal line and a state of an Ry/By signal line in an overlapping manner.

In the diagrams illustrating the states of the respective memory cell arrays 121, a period for which the memory cell array 121 is placed in the RS state is indicated by a hatched bar. A period for which the memory cell array 121 is placed in the NS state is indicated by a white bar.

In the respective timing charts of FIG. 17, the plane 120-0 is denoted by P0 and the plane 120-1 is denoted by P1.

The memory controller 200 first transmits a set feature command for setting the voltage Vrs to the memory chip 100-0 (S501). Subsequently, the memory controller 200 transmits an RS entry command for the plane 120-1 (S502). The processing circuit 110 of the memory chip 100-0 causes the memory cell array 121 of the plane 120-1 to transition from the NS state to the RS state in response to the RS entry command for the plane 120-1.

Subsequently, the memory controller 200 transmits a read command for the plane 120-0 as a read target (S503), and the processing circuit 110 of the memory chip 100-0 executes a read operation on the memory cell array 121 of the plane 120-0 in response to the read command. During the read operation, the Ry/By signal line is maintained in a busy state. After completion of the read operation, the memory controller 200 acquires data from the memory chip 100-0 (S504).

After acquiring the data, the memory controller 200 transmits an RS entry command for the plane 120-0 (S505). The processing circuit 110 of the memory chip 100-0 causes the memory cell array 121 of the plane 120-0 to transition from the NS state to the RS state in response to the RS entry command for the plane 120-0.

Subsequently, the memory controller 200 transmits an RS exit command for the plane 120-1 (S506). The processing circuit 110 of the memory chip 100-0 causes the memory cell array 121 of the plane 120-1 to transition from the RS state to the NS state in response to the RS exit command for the plane 120-1.

Subsequent to S506, the memory controller 200 transmits a program command for the plane 120-1 (S507). The processing circuit 110 of the memory chip 100-0 executes a program operation on the memory cell array 121 of the plane 120-1 in response to the program command. During the program operation, the Ry/By signal line is maintained in a busy state.

After completion of the program operation, the memory controller 200 transmits an RS entry command for the plane 120-1 again (S508). The processing circuit 110 of the memory chip 100-0 causes the memory cell array 121 of the plane 120-1 to transition from the NS state to the RS state in response to the RS entry command for the plane 120-1.

Subsequently, the memory controller 200 transmits an RS exit command for the plane 120-0 (S509). The processing circuit 110 of the memory chip 100-0 causes the memory cell array 121 of the plane 120-1 to transition from the RS state to the NS state in response to the RS exit command for the plane 120-0.

Subsequent to S509, the memory controller 200 transmits an erase command for the plane 120-0 (S510). The processing circuit 110 of the memory chip 100-0 executes an erase operation on the memory cell array 121 of the plane 120-0 in response to the erase command. During the program operation, the Ry/By signal line is maintained in a busy state.

The memory controller 200 first transmits the set feature command for setting the voltage Vrs to the memory chip 100-1 (S521). Subsequently, the memory controller 200 transmits an RS entry command for the plane 120-0 (S522). In the memory chip 100-1, the processing circuit 110 causes the memory cell array 121 of the plane 120-0 to transition from the NS state to the RS state in response to the RS entry command for the plane 120-0.

The memory controller 200 transmits an erase command for the plane 120-1 (S523). The processing circuit 110 of the memory chip 100-1 executes an erase operation on the memory cell array 121 of the plane 120-1 in response to the erase command. During the erase operation, the Ry/By signal line is maintained in a busy state.

After end of the erase operation, the memory controller 200 transmits a program command for the plane 120-1 (S524). The processing circuit 110 of the memory chip 100-1 executes a program operation on the memory cell array 121 of the plane 120-1 in response to the program command. During the program operation, the Ry/By signal line is maintained in a busy state.

After end of the program operation, the memory controller 200 transmits an RS entry command for the plane 120-1 (S525). The processing circuit 110 of the memory chip 100-1 causes the memory cell array 121 of the plane 120-1 to transition from the NS state to the RS state in response to the RS entry command for the plane 120-1.

The memory controller 200 transmits an RS exit command for the plane 120-0 (S526). The processing circuit 110 of the memory chip 100-1 causes the memory cell array 121 of the plane 120-0 to transition from the RS state to the NS state in response to the RS exit command for the plane 120-0.

Subsequently, the memory controller 200 transmits a read command for the plane 120-0 (S527). The processing circuit 110 of the memory chip 100-1 executes a read operation on the memory cell array 121 of the plane 120-0 in response to the read command. During the read operation, the Ry/By signal line is maintained in a busy state. After end of the read operation, the memory controller 200 acquires data from the memory chip 100-1 (S528).

After acquiring the data, the memory controller 200 transmits an RS entry command for the plane 120-0 (S529). The processing circuit 110 of the memory chip 100-1 causes the memory cell array 121 of the plane 120-0 to transition from the NS state to the RS state in response to the RS entry command for the plane 120-0.

Thus, the memory controller 200 can asynchronously transmit various commands including the RS entry command and the RS exit command to each of the memory chips 100, as with the first embodiment. As a result, the memory controller 200 can control the memory cell array 121 to transition between the states in units of the memory chips 100.

Further, the memory controller 200 can designate the memory cell 121 to be caused to transition to the RS state in units of the planes 120 by the RS entry command. That is, the memory controller 200 can control the state transition of the memory cell array 121 in units of the planes 120.

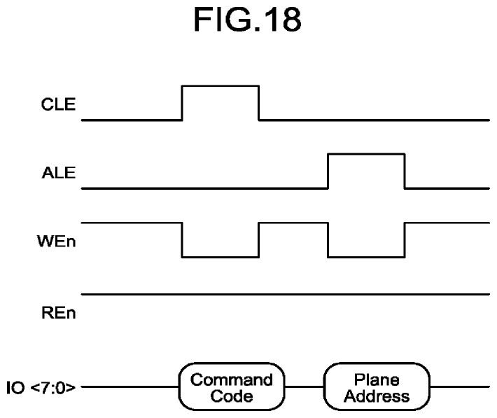

FIG. 18 is a diagram illustrating an example of state transition of various signal lines in transmitting the RS entry command and the RS exit command according to the second embodiment.

In the example illustrated in FIG. 18, the CLE signal and the ALE signal make a positive logic transition, and the WE signal and the RE signal make a negative logic transition. The IO signal has a bit width of 8 bits as an example. The logic of the transition of each signal is not limited to the above logic. The bit width of the IO signal is not limited to the above bit width.

To control the state transition of the memory cell array 121 in units of the planes 120, the RS entry command and the RS exit command are accompanied by an address value to specify the plane 120. This address value is referred to as a plain address.

That is, a command code indicating the RS entry command or the RS exit command and the plane address are transferred to an IO signal line as illustrated in FIG. 18. While the command code is being transferred, the CLE signal is maintained in a HIGH state, and the WE signal is maintained in a LOW state. In the period for which the CLE signal is maintained in the HIGH state, the command user interface 112 acquires, as a command, information transferred from the IO signal line.

While the plane address is being transferred, the ALE signal is maintained in a HIGH state, and the WE signal is maintained in a LOW state. In the period for which the ALE signal is maintained in the HIGH state, the command user interface 112 acquires information transferred from the IO signal line as an address.

In this manner, the memory chip 100 includes the multiple planes 120 each of which is specified by the address value in the second embodiment. Each of the planes 120 includes the memory cell array 121. The RS entry command includes the address value to designate a single plane 120. The processing circuit 110 causes the memory cell array 121 of one of the planes 120, indicated by the address value included in the RS entry command, to transition to the RS state.

That is, the memory controller 200 according to the second embodiment can control the state of the memory cell array 121 in units of the planes 120.

The memory controller 200 may be configured to control the state of the memory cell array 121 in units of the blocks BLK. In such a case, the RS entry command includes a block address.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system connectable to a host, the memory system comprising:
a memory controller; and
a memory chip comprising a first storage area and a processing circuit, the first storage area including a plurality of word lines, wherein
the memory controller is configured to cause the processing circuit to execute a first access to the first storage area, transmit a first command to the memory chip after completion of the first access, and transmit a second command to the memory chip before causing the processing circuit to execute a second access subsequent to the first access, and
the processing circuit is configured to start applying a first voltage to the word lines in response to the first command, and end applying the first voltage to the word lines in response to the second command.

2. The memory system according to claim 1, wherein
the processing circuit is configured to execute a read access,
in the read access, the processing circuit applies a second voltage to a first word line connected to a first memory cell to be read, and applies a third voltage to a second word line connected to a second memory cell not to be read, and
the first voltage is lower than the third voltage.

3. The memory system according to claim 2, wherein
the processing circuit comprises:
a first regulator configured to generate the second voltage; and
a second regulator configured to generate the first voltage and the third voltage.

4. The memory system according to claim 1, wherein
the first storage area includes a plurality of second storage areas which is designated by different address values by the memory controller,
the first command includes an address value, and
the processing circuit is configured to start applying the first voltage to a word line of one of the second storage areas, the one of the second storage areas corresponding to the address value included in the first command.

5. The memory system according to claim 1, further comprising
a temperature sensor, wherein
the memory controller is configured to determine whether to transmit the first command in accordance with a value detected by the temperature sensor.

6. The memory system according to claim 1, wherein
the memory system is operable in both a first mode and a second mode, the second mode being lower in power consumption than the first mode, and
the memory controller is configured to determine whether to transmit the first command in accordance with receipt or non-receipt of a request for transition to the second mode from the host.

7. The memory system according to claim 1, wherein
the memory controller is configured to count the number of P/E cycles, and
the memory controller is configured to determine whether to transmit the first command in accordance with a count value of the number of P/E cycles.

8. The memory system according to claim 1, wherein
the memory controller is configured to transmit, to the memory chip, a third command for setting a value of the first voltage, and
the processing circuit is configured to apply a voltage of the value set by the third command as the first voltage.

9. The memory system according to claim 8, further comprising
a temperature sensor, wherein
the memory controller is configured to set a value corresponding to a value detected by the temperature sensor, by the third command.

10. The memory system according to claim 8, wherein
the memory system is operable in both a first mode and a plurality of second modes, the second modes being lower in power consumption than the first mode and associated with different priorities, and
in a third mode, the memory controller is configured to set a value according to a priority associated with the third mode, by the third command, the third mode being one of the second modes.

11. The memory system according to claim 8, wherein
the memory controller is configured to manage the number of P/E cycles, and
the memory controller is configured to set a value corresponding to a count value of the number of P/E cycles, by the third command.

12. The memory system according to claim 1, wherein
the processing circuit is configured to execute a read access, and
the processing circuit comprises:
a first regulator that is configured to generate a second voltage for a first word line connected to a first memory cell, the first memory cell being a read target in the read access, the second voltage being for determining a threshold voltage of the first memory cell; and
a second regulator that is configured to generate a third voltage for a second word line connected to a second memory cell and generate the first voltage in response to the first command, the second memory cell not being a read target in the read access, the third voltage being for turning on the second memory cell.
